(19) United States
(12) Patent Application Publication
(10) Pub. No.: US 2009/0136235 A1
(43) Pub. Date: May 28, 2009

(54) Probe card with optical transmitting unit and memory tester having the same

(75) Inventors: Sung-dong Suh, Seoul (KR); Kyoung-ho Ha, Seoul (KR); Seong-gu Kim, Pyeongtaek-si (KR); Soo-haeng Cho, Suwon-si (KR); Bok-ki Min, Suwon-si (KR); Han-youl Ryu, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/149,721

(22) Filed: May 7, 2008

(30) Foreign Application Priority Data
Nov. 23, 2007 (KR) 10-2007-0120355

(51) Int. Cl. H04B 10/00; G01R 31/28

(52) U.S. Cl. 398/135; 324/754

(57) ABSTRACT

Example embodiments provide a probe card having an optical transmitting unit and a memory tester having the probe card. The probe card may include a plurality of needles connected to test terminals formed in a memory, a plurality of first terminals connected to the needles, a plurality of second terminals connected to the outside and corresponding to the first terminals, and an optical transmitting unit. The optical transmitting unit may connect the first terminals and the second terminals.

### FOREIGN PRIORITY STATEMENT

This application claims priority under 35 U.S.C. § 119 to Korean Patent Application No. 10-2007-0120355, filed on Nov. 23, 2007, in the Korean Intellectual Property Office, the entire contents of which are incorporated herein by reference.

### BACKGROUND

1. Field

Example embodiments are directed to a probe card and a memory tester having the probe card, and more particularly, to a probe card having an optical transmitting unit and a memory tester having the probe card.

2. Related Art

A conventional memory tester may include a probe card connected to electrode pads of a device under test (DUT). The probe card may connect the DUT to a test control system. A test input signal may be applied to the DUT from the test control system through the probe card, and an output signal may be transmitted to the test control system from the DUT through the probe card. The test control system may distinguish a functional product from a defective product by comparing the transmitted output signal with an expected signal value, for example.

If the integration density of the DUT increases, the test time for DUT testing may increase. For example, if the time required for testing a 64 MB dynamic random access memory (DRAM) is T, testing a 256 MB DRAM may require 4T, and testing a 1 GB DRAM may require 16T. The test time may increase as the density and/or speed of DRAMs increases. Also, due to the number of wires required for processing signals in a probe card, signal distortion and/or signal reduction phenomenon in a printed circuit board of the probe card may occur, and the ability of the DUT to be tested may be reduced.

### SUMMARY

Example embodiments provide a probe card that may have an optical transmitting unit that transmits a signal between two terminals, and a memory tester that may have the probe card.

A probe card may include a plurality of needles connected to test terminals of a memory, a plurality of first terminals connected to the plurality of needles, a plurality of second terminals connected to a testing support unit and corresponding to the plurality of first terminals, and a plurality of optical transmitting units, each optical transmitting unit connecting one of the plurality of first terminals and one of the plurality of second terminals.

The optical transmitting unit may include a first optical fiber that transmits light from one of the plurality of first terminals to one of the plurality of second terminals, and a second optical fiber that transmits light from one of the plurality of second terminals to one of the plurality of first terminals.

A probe card may further include a first bidirectional switch that selectively connects one of the plurality of first terminals to the first optical fiber or the second optical fiber, and a second bidirectional switch that selectively connects one of the plurality of second terminals to the first optical fiber or the second optical fiber.

The first bidirectional switch may selectively connect one of the plurality of first terminals to the first optical fiber or the second optical fiber according to a first control voltage. The second bidirectional switch may selectively connect one of the plurality of second terminals to the first optical fiber or the second optical fiber according to a second control voltage.

The first bidirectional switch and the second bidirectional switch may be single pole double throw switches.

A probe card may include a first light emitting unit driver and a first light emitting unit, which may be provided between the first optical fiber and one of the plurality of first terminals, a first light receiving unit driver and a first light receiving unit, which may be provided between the first optical fiber and one of the plurality of second terminals, a second light emitting unit driver and a second light emitting unit, which may be provided between the second optical fiber and one of the plurality of second terminals, and a second light receiving unit driver and a second light receiving unit, which may be provided between the second optical fiber and one of the plurality of first terminals.

The first light emitting unit and the second light emitting unit may be vertical cavity surface emitting lasers configured to emit an infrared ray, and wherein the first light receiving unit and the second light receiving unit may be photo diodes configured to detect an infrared ray.

A memory tester may include a probe card that transmits and receives an electrical signal to and from a memory, and the probe card may include a plurality of needles connected to test terminals of a memory, a plurality of first terminals connected to the plurality of needles, a plurality of second terminals connected to a testing support unit and corresponding to the plurality of first terminals, and a plurality of optical transmitting units, each optical transmitting unit connecting one of the plurality of first terminals and one of the plurality of corresponding second terminals.

The testing support unit may include a plurality of testing support terminals connected to the plurality of the second terminals.

The testing support unit and the probe card may be capable of transmitting and receiving a digital signal.

### BRIEF DESCRIPTION OF THE DRAWINGS

The above and other features and advantages of example embodiments will become more apparent by describing them in detail with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a schematic cross-sectional view of a memory tester according to example embodiments.

FIG. 2 is a schematic drawing of a configuration of a probe card of FIG. 1 according to example embodiments.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

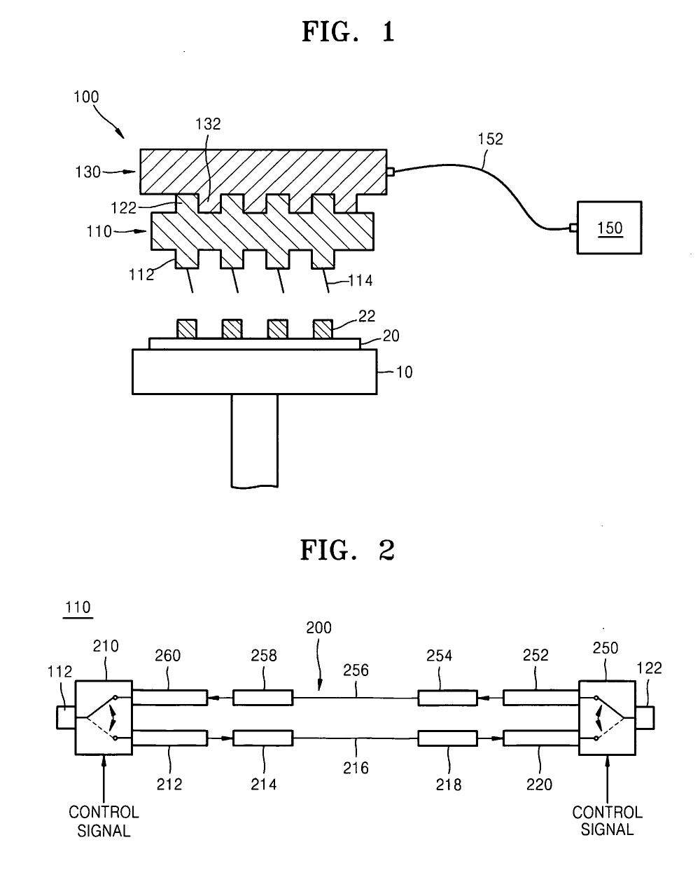

FIG. 1 is a schematic cross-sectional view of a memory tester 100 according to example embodiments.

Referring to FIG. 1, the memory tester 100 that may have an optical transmitting unit may include a probe card 110 to be connected to a memory of a wafer 20 to be tested, a tester head 130 connected to the probe card 110, and/or a control unit 150 which may be connected to the tester head 130 via an optical cable 152 (as shown in FIG. 1) and/or a wireless connection or other connection.

The memory of the wafer 20 may be one memory device in the wafer 20, for example. The wafer 20 may contact the probe card 110 on a stage 10. Electrode pads 22 for testing may be formed on an upper surface of the memory of the wafer 20. The probe card 110 may include first terminals 112 for connecting the probe card 110 to the memory of the wafer 20 and second terminals 122 for connecting the probe card 110 to the tester head 130. Each of the first terminals 112 may include a needle 114 to contact the electrode pads 22 of the memory of the wafer 20. For example, micro-spring interposers (not shown in FIG. 1), which are wires for connecting the first terminals 112 and the needles 114 and a multi-layer ceramic (MLC) that fixes the wires, may be formed between the first terminals 112 and the needles 114. The tester head 130 may be disposed on the probe card 110 to support the probe card 110. The tester head 130 may include terminals 132 that contact the second terminals 122 of the probe card 110. The tester head 130 may transmit a digital signal received from the control unit 150 to the probe card 110, and may transmit a digital signal received from the probe card 110 to the control unit 150.

The control unit 150 may output a test signal to the probe card 110 via the tester head 130, and may determine whether the memory is functional or defective by analyzing the test signal received from the probe card 110.

FIG. 1 illustrates a schematic cross-sectional view of an example embodiment of the memory tester 100, but the shape of the memory tester 100 is not limited to the shape illustrated in FIG. 1. The shapes of the tester head 130, the terminals 132, the probe card 110, the first terminals 112, the second terminals 122, the needles 114, the wafer 20, the electrode pads 22, the stage 10, the control unit 150 and the optical wire 152 are not limited to example embodiments illustrated in FIG. 1. For example, the shape of the tester head 130 may correspond to the shape of the probe card 110, the shape of the probe card 110 may correspond to the shape of the wafer 20, the shape of the terminals 132 may correspond to the shape of the second terminals 122, the shape of the first terminals 112 may correspond to the shape of the electrode pads 22, the shape of the needles 114 may correspond to the shape of the electrode pads 22, and/or the shape of the stage 10 may correspond to the shape of the wafer 20.

FIG. 2 is a schematic drawing of a configuration of the probe card 110 of FIG. 1 according to example embodiments.

Referring to FIG. 2, the probe card 110 may include a first terminal 112 connected to a needle 114 that may contact the electrode pad 22 of the wafer 20 and a second terminal 122 connected to the tester head 130. The first terminal 112 may be connected to the needle 114 which corresponds to the electrode pad 22. The needle 114 may be directly connected to the electrode pad 22, or for example may be connected through a wire and/or a wireless connection (not shown in FIG. 2). The second terminal 122 may be formed to correspond to the first terminal 112. The second terminal 122 may be electrically connected to the terminal 132 of the tester head 130.

The first terminal 112 and the second terminal 122 may be connected to each other via an optical transmitting unit 200. The optical transmitting unit 200 may include a first optical fiber 216 that transmits light from the first terminal 112 to the second terminal 122 and a second optical fiber 256 that transmits light from the second terminal 122 to the first terminal 112.

A first light emitting unit driver 212 and a first light emitting unit 214 may be provided between the first optical fiber 216 and the first terminal 112. A first light receiving unit driver 220 and a first light receiving unit 218 may be provided between the first optical fiber 216 and the second terminal 122. A second light emitting unit driver 252 and a second light emitting unit 254 may be provided between the second optical fiber 256 and the second terminal 122. A second light receiving unit driver 260 and a second light receiving unit 258 may be provided between the first optical fiber 256 and the first terminal 112. The first light emitting unit 214 and the second light emitting unit 254 may be laser diodes, and for example may be vertical cavity surface emitting lasers (VCSELs). VCSELs may be small in size, and may emit infrared rays having wavelengths of 850 nm, 1310 nm, and 1550 nm, for example. The first light receiving unit 218 and the second light receiving unit 258 may be photodiodes that detect wavelengths of the first light emitting unit 214 and the second light emitting unit 254, respectively.

The first optical fiber 216 and the second optical fiber 256 may be connected between the first terminal 112 and the second terminal 122. In order to connect the first terminal 112 to both of the first optical fiber 216 and the second optical fiber 256, a first bi-directional switch 210 may be disposed therebetween, and in order to connect the second terminal 122 to both of the first optical fiber 216 and the second optical fiber 256, a second bi-directional switch 250 may be disposed therebetween. The first and second bi-directional switches 210 and 250 may be single pole-double throw (SPDT) switches, for example.

The first bi-directional switch 210 may selectively connect the first terminal 112 to the first optical fiber 216 and the second optical fiber 256. The first bidirectional switch 210 may connect the first terminal 112 to the first optical fiber 216 or the second optical fiber 256 according to a control voltage applied to the first bidirectional switch 210.

The second bi-directional switch 250 may selectively connect the second terminal 122 to the first optical fiber 216 and the second optical fiber 256. The second bidirectional switch 250 may connect the second terminal 122 to the first optical fiber 216 or the second optical fiber 256 according to a control voltage applied to the second bidirectional switch 250.

A method of operating the probe card 110 that may have an optical transmitting unit and the memory tester 100 having the probe card 110 according to example embodiments will now be described.

First, the electrode pads 22 may be placed in contact with the needles 114 of the probe card 110. Each of the needles 114 may contact each of the electrode pads 22, for example.

The control unit 150 may transmit a signal, such as an RF pulse signal for example, which is a test signal to the tester head 130. The tester head 130 may transmit the inputted signal to the second terminals 122. A control voltage may be applied to the second bidirectional switch 250, and the second bidirectional switch 250 may be connected to the second light emitting unit driver 252. The second light emitting unit driver 252 may drive the second light emitting unit 254 in response to the inputted signal to transmit an optical signal to the second light receiving unit 258 through the second optical fiber 256.

The second light receiving unit 258 connected to the second optical fiber 256 may generate an electrical signal by receiving the optical signal from the second light emitting unit 254, and the second light receiving unit driver 260 may generate a pulse voltage signal in response to the electrical signal. A control voltage may be applied in advance to the first bi-directional switch 210, and the second light receiving unit driver 260 may be connected to the first terminal 112. The pulse voltage signal transmitted from the second light receiving unit driver 260 may be applied to the electrode pads 22 of the memory 20 of the wafer 20 to be tested, and a response voltage generated from the memory 20 may be transmitted to the first terminal 112. At this point, the first bidirectional switch 210 may be connected to the first light emitting unit driver 212 in advance by a control voltage, and the response voltage may be transmitted to the first light emitting unit driver 212. The first light emitting unit driver 212 may drive the first light emitting unit 214 in response to the voltage signal, and the first light emitting unit 214 may generate a given pulse optical signal. The pulse optical signal may be transmitted to the first light receiving unit 218 via the first optical fiber 216, and the first light receiving unit 218 may generate a current in response to the pulse optical signal. The first light receiving unit driver 220 may generate a pulse voltage signal in response to the current received from the first light receiving unit 218. The pulse voltage signal may be transmitted to the control unit 150 via the second bi-directional switch 250 connected to the second terminal 122, the tester head 130, and the communication cable 132. The control unit 150 may determine whether the memory 20 is functional or defective by comparing the pulse voltage signal with a reference signal.

Because the probe card 110 according to example embodiments includes an optical transmitting unit, signal distortion and a signal reduction phenomenon in the probe card 110 may be reduced or prevented.

Also, if a bi-directional switch is used in the optical transmitting unit according to example embodiments, two optical fibers may be connected to first and second terminals, and example embodiments of the optical transmitting unit may be applied to a memory tester.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A probe card comprising:
a plurality of needles connected to test terminals of a memory,
a plurality of first terminals connected to the plurality of needles,
a plurality of second terminals connected to a testing support unit and corresponding to the plurality of first terminals, and
a plurality of optical transmitting units, each optical transmitting unit connecting one of the plurality of first terminals and one of the plurality of second terminals.

2. The probe card of claim 1, wherein the optical transmitting unit comprises:
a first optical fiber that transmits light from one of the plurality of first terminals to one of the plurality of second terminals, and
a second optical fiber that transmits light from one of the plurality of second terminals to one of the plurality of first terminals.

3. The probe card of claim 2, further comprising:
a first bidirectional switch that selectively connects one of the plurality of first terminals to the first optical fiber or the second optical fiber, and
a second bidirectional switch that selectively connects one of the plurality of second terminals to the first optical fiber or the second optical fiber.

4. The probe card of claim 3, wherein the first bidirectional switch selectively connects one of the plurality of first terminals to the first optical fiber or the second optical fiber according to a first control voltage, and wherein
the second bidirectional switch selectively connects one of the plurality of second terminals to the first optical fiber or the second optical fiber according to a second control voltage.

5. The probe card of claim 3, wherein the first bidirectional switch and the second bidirectional switch are single pole double throw switches.

6. The probe card of claim 2, further comprising:
a first light emitting unit driver and a first light emitting unit, which are provided between the first optical fiber and one of the plurality of first terminals,
a first light receiving unit driver and a first light receiving unit, which are provided between the first optical fiber and one of the plurality of second terminals,
a second light emitting unit driver and a second light emitting unit, which are provided between the second optical fiber and one of the plurality of second terminals, and
a second light receiving unit driver and a second light receiving unit, which are provided between the second optical fiber and one of the plurality of first terminals.

7. The probe card of claim 6, wherein the first light emitting unit and the second light emitting unit are vertical cavity surface emitting lasers configured to emit an infrared ray, and wherein
the first light receiving unit and the second light receiving unit are photo diodes configured to detect an infrared ray.

8. A memory tester comprising a probe card that transmits and receives an electrical signal to and from a memory, wherein the probe card comprises:
a plurality of needles connected to test terminals of a memory,
a plurality of first terminals connected to the plurality of needles,
a plurality of second terminals connected to a testing support unit and corresponding to the plurality of first terminals, and
a plurality of optical transmitting units, each optical transmitting unit connecting one of the plurality of first terminals and one of the plurality of corresponding second terminals.

9. The memory tester of claim 8, wherein the optical transmitting unit comprises:
a first optical fiber that transmits light from one of the plurality of first terminals to one of the plurality of second terminals, and
a second optical fiber that transmits light from one of the plurality of second terminals to one of the plurality of first terminals.

10. The memory tester of claim 9, wherein the probe card further comprises:
a first bidirectional switch that selectively connects one of the plurality of first terminals to the first optical fiber or the second optical fiber, and
a second bidirectional switch that selectively connects one of the plurality of second terminals to the first optical fiber or the second optical fiber.

11. The memory tester of claim 10, wherein the first bidirectional switch selectively connects one of the plurality of first terminals to the first optical fiber or the second optical fiber according to a first control voltage, and wherein
the second bidirectional switch selectively connects one of the plurality of second terminals to the first optical fiber or the second optical fiber according to a second control voltage.

12. The memory tester of claim 10, wherein the first bidirectional switch and the second bidirectional switch are single pole double throw switches.

13. The memory tester of claim 9, further comprising:
a first light emitting unit driver and a first light emitting unit, which are provided between the first optical fiber and one of the plurality of first terminals,
a first light receiving unit driver and a first light receiving unit, which are provided between the first optical fiber and one of the plurality of second terminals,
a second light emitting unit driver and a second light emitting unit, which are provided between the second optical fiber and one of the plurality of second terminals, and
a second light receiving unit driver and a second light receiving unit, which are provided between the second optical fiber and one of the plurality of first terminals.

14. The memory tester of claim 13, wherein the first light emitting unit and the second light emitting unit are vertical cavity surface emitting lasers configured to emit an infrared ray, and wherein
the first light receiving unit and the second light receiving unit are photo diodes configured to detect an infrared ray.

15. The memory tester of claim 8, wherein the testing support unit comprises a plurality of testing support terminals connected to the plurality of the second terminals.

16. The memory tester of claim 8, wherein the testing support unit and the probe card are capable of transmitting and receiving a digital signal.
